(19) United States
(12) Patent Application Publication
(10) Pub. No.: US 2011/0186101 A1
(43) Pub. Date: Aug. 4, 2011

(54) THERMOELECTRIC CONVERSION USING METAL-ION SOLUTIONS

(76) Inventor: Thomas John Melanson, Hilton Head, SC (US)

(21) Appl. No.: 12/700,600

(22) Filed: Feb. 4, 2010

(51) Int. Cl. H01L 35/28

(52) U.S. Cl. 136/203

(57) ABSTRACT

A thermoelectric conversion device may be made of a pair of dissimilar materials conductively joined at opposite sides, wherein at least one of said materials is a metal ion liquid solution. A thermal differential between the opposite sides creates an electric current flow and the liquid metal ion solution resists thermal equilibrium. The liquid metal ion solution may be contained by a substantially nonconductive material, such as vinyl tubing. A plurality of pairs of these dissimilar materials may be joined in series to increase the current output. The metal ion of the liquid solution may be selected, for example, from a group consisting of Lithium (Li), Sodium (Na), and Potassium (K).

### RELATED APPLICATION

This application claims the benefit of U.S. Provisional Patent Application No. 61/153,051 filed Feb. 17, 2009.

### TECHNICAL FIELD

A method of creating an electrical current using a metal-ion liquid solution based on the Seebeck effect. This method may be incorporated into a thermoelectric device and used to convert heat into an electrical current.

### BACKGROUND

The basic theory of operation of thermoelectric devices has been developed and employed for many years. Solid state thermoelectric devices have been based on the Seebeck effect, which is created when two dissimilar materials (Seebeck materials) arc joined at both ends using a thermal and electrically conductive junction. When the two junctions are subjected to a temperature gradient (one junction is hot, the other cold), this results in a current flow across the materials.

U.S. Pat. No. 5,610,366, issued Mar. 11, 1997 to Fleurial discloses a formula for the use of Seebeck devices to convert heat into an electric current expressed as a dimensionless “Figure of Merit” (Z). This equation is defined as:

Z=S²(δ/γ)

where:

S=Seebeck Effect

δ=Electrical Conductivity

γ=Thermal Conductivity

Thermoelectric Seebeck devices using materials such as alloys of Bismuth, Teluride (Tellurium), Lead-teluride, and Bismuth-Lead were developed 30-40 years ago. More recently, semi-conductor materials (such as Germanium and Silicon) have also been used, including the use of doped compounds to change the crystalline or matrix properties.

Additional approaches are shown in U.S. Pat. No. 7,365,265, issued Apr. 29, 2008 to Heremans, et al., which discloses that adding inclusions in the metallic matrix may further boost the efficiency of these devices.

These approaches require the use of exotic materials and processing, and are difficult and/or expensive to manufacture. This limits their commercial applications to highly specialized industries, such as aerospace, or to extremely low output requirements (such as sensors). This cost of materials and manufacture, combined with the relatively low yields of Seebeck devices, make them impractical for common use as electrical generating devices.

An unfilled need exists for a thermoelectric device that uses common, inexpensive materials and is relatively easy to manufacture.

### SUMMARY OF THE INVENTION

The present invention improves on the Seebeck effect, as defined by the Figure of Merit, by using a novel approach to increase the ratio of the Electrical Conductivity over Thermal Conductivity. This invention results in a better performance without use of expensive or exotic materials.

This beneficial effect is accomplished according to the present invention by replacing at least one (or both) of the Seebeck materials with a metal ion liquid solution with good electrical conductivity. The use of a liquid solution, and not a solid or crystalline matrix, allows the Thermal Conductivity to decrease faster than the Electrical Conductivity, thereby increasing the overall Seebeck effect and resisting thermal equilibrium.

The present invention also has the benefit that the device can operate in a nominal pressure and temperature environment, and is functional when the cool junction is at 0-10 degrees C. (just above the freezing point of the solution) and the hot junction is at 70-90 degrees C. (just below the boiling point of the solution). Because the device does not require temperature extremes, this allows for a wider range of available heat sources, such as solar, heat of combustion, capture of waste heat, and such.

Additionally, metal-ion liquid solutions are much simpler to produce, and can be produced at a lower cost then exotic metal alloys, which allows for a wider range of commercial applications.

### BRIEF DESCRIPTION OF THE DRAWING

Like reference numerals are use to indicate like parts thorough the various figures of the drawing, wherein:

FIG. 1 is a schematic illustration of a Seebeck device according to a preferred embodiment of the present invention; and

FIG. 2 is a schematic illustration of an alternate embodiment of the present invention.

### DETAILED DESCRIPTION OF THE INVENTION

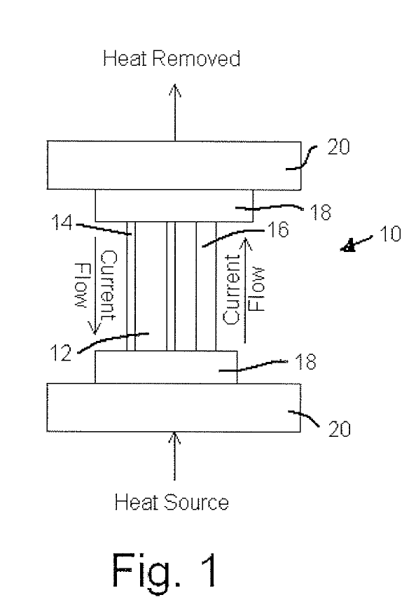

Referring first to FIG. 1, therein is shown at 10 a preferred embodiment of the present invention in which at least one or both of the Seebeck materials is replaced by metal-ion solutions. For example, a metal ion liquid solution 12 consisting essentially of 10% weight per volume of Lithium Chloride in distilled water, may be contained in vinyl tubing 14. The containment material may be any material that has poor thermal and electrical connectivity. The other Seebeck material 16 may be a copper wire, used as a dissimilar material for producing the Seebeck effect. A lead connection 18, a material with good thermal and electrical conductive properties, may be used to connect adjacent ends of the Seebeck materials 12, 16 and acts as the thermal and electrical junction combining the two Seebeck materials at the hot and cold junctions. Distilled water 20, or other material with good heat capacity and minimal electrical conductivity, may be used as the vehicle to transfer heat to and/or from the device 10.

In preferred form, the type of metal ion selected is one that is easily ionized and soluble, for example selected from the group of Lithium (Li), Sodium (Na), and Potassium (K).

Electron migration through the metal-ion Seebeck material 12 may be further enhanced by the addition of high surface area materials to the solution that act as a substrate for ionic reaction. For example:

Li⁺+e⁻ [symbol] Li

One example is to add 50% by weight activated carbon to the solution 12 in FIG. 1. This additive further supports the effect by acting as a substrate for the ions to deposit out as solid metal, acting as a metal reservoir that improves electron transport through the material.

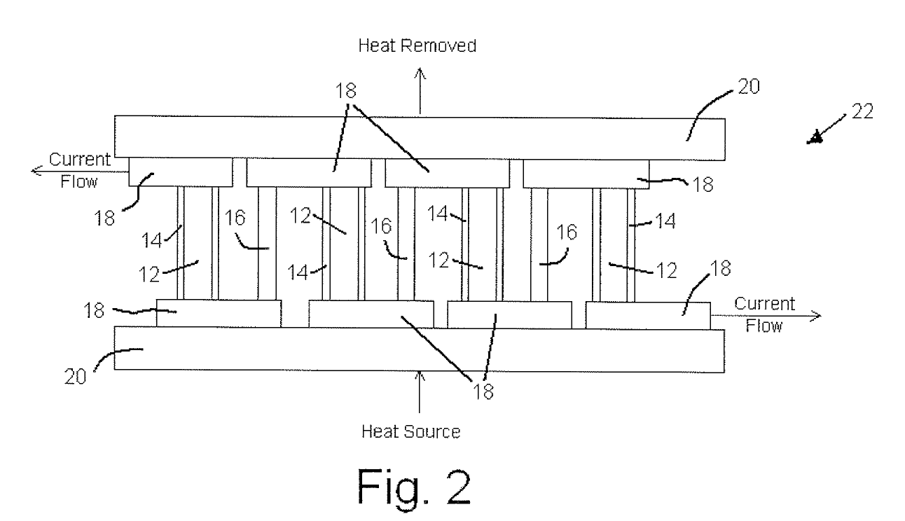

As schematically illustrated in FIG. 2, the overall voltage of a Seebeck device 22 can be increased by combining pairs of dissimilar materials 12, 16 in series.

It can readily be seen that there are numerous benefits that result from employing the concepts of the present invention. The foregoing description of a preferred embodiment has been presented for purposes of illustration and description. It is not intended to be exhaustive or to limit the invention to the precise form disclosed. Obvious modifications or variations are possible in light of the above teachings. The scope of my patent protection is not to be limited by the examples given, but only by the following claim or claims, interpreted according to applicable legal standards and doctrines, including the doctrine of equivalents.

What I claim is:

1. A thermoelectric conversion device, comprising:
a pair of dissimilar materials conductively joined at opposite sides, wherein at least one of said materials is a metal ion liquid solution;
whereby a thermal differential between the opposite sides creates an electric current flow and said liquid metal ion solution resists thermal equilibrium.

2. The thermoelectric conversion device of claim 1, wherein the liquid metal ion solution is contained by a substantially nonconductive material.

3. The thermoelectric conversion device of claim 2, wherein the substantially nonconductive material is vinyl tubing.

4. The thermoelectric conversion device of claim 1, wherein a plurality of pairs of said dissimilar materials are joined in series.

5. The thermoelectric conversion device of claim 1, wherein the metal ion of the liquid solution is selected from a group consisting of Lithium (Li), Sodium (Na), and Potassium (K).
